(19) United States
(12) Patent Application Publication
(10) Pub. No.: US 2017/0162401 A1
(43) Pub. Date: Jun. 8, 2017

(54) BAFFLE PLATE, PLASMA PROCESSING APPARATUS USING THE SAME, SUBSTRATE PROCESSING APPARATUS AND METHOD OF PROCESSING SUBSTRATE

(71) Applicant: SAMSUNG ELECTRONICS CO., LTD., SUWON-SI (KR)

(72) Inventors: SUNG-HO KANG, OSAN-SI (KR); KI-CHUL KIM, SEONGNAM-SI (KR); JAE-HYUN LEE, YONGIN-SI (KR); PYUNG MOON, SEOUL (KR); HAN-KI LEE, HWASEONG-SI (KR); UN-KI KIM, SUWON-SI (KR)

(21) Appl. No.: 15/269,036

(22) Filed: Sep. 19, 2016

(30) Foreign Application Priority Data
Dec. 4, 2015 (KR) 10-2015-0172658

(51) Int. Cl. H01L 21/324; C23C 16/50; H01L 21/30; H01L 21/687; H01L 21/67; H01J 37/32; C23C 16/458

(52) U.S. Cl. CPC H01L 21/324; H01J 37/32633; H01J 37/32715; H01J 37/32082; C23C 16/50; C23C 16/458; H01L 21/68757; H01L 21/67115; H01L 21/3003; H01J 2237/33

(57) ABSTRACT

A plasma processing apparatus includes a susceptor, a chamber housing that accommodates the susceptor and encloses a reaction space, and an annular shaped baffle plate that annularly surrounds the susceptor. The baffle plate includes a first layer that includes a conductive material and a second layer that includes a non-conductive material, and the second layer is closer to the reaction space than the first layer.

### CROSS-REFERENCE TO RELATED APPLICATION

This application claims priority under 35 USC §119 from, and the benefit of, Korean Patent Application No. 10-2015-0172658, filed on Dec. 4, 2015 in the Korean Intellectual Property Office, the contents of which are herein incorporated by reference in their entirety.

### BACKGROUND

Technical Field

Embodiments of the inventive concept are directed to a baffle plate, a plasma processing apparatus using the same, a substrate processing apparatus and a method of processing a substrate. More specifically, embodiments of the inventive concept are directed to a baffle plate, a plasma processing apparatus and a method of processing a substrate that reduces particle contamination by preventing or reducing the generation of an arc.

Discussion of the Related Art

As the sizes of semiconductor devices are reduced, a resistance of certain regions of a semiconductor device may decrease. However, due to crystallographic defects that can occur during a manufacturing process of a semiconductor device, the resistance of the certain regions of a semiconductor device may not be reduced to a desired value. Such defects can be cured by an annealing treatment using hydrogen plasma. However, when an annealing treatment is performed in a plasma processing apparatus using a hydrogen plasma, an arc is frequently generated, which can cause particle contamination.

### SUMMARY

According to an example embodiment of the inventive concept, a plasma processing apparatus includes a susceptor, a chamber housing that accommodates the susceptor and encloses a reaction space, and an annular baffle plate that surrounds the susceptor. The baffle plate includes a first layer that includes a conductive material and a second layer that includes a non-conductive material, and the second layer is closer to the reaction space than the first layer.

According to an example embodiment of the inventive concept, a substrate processing apparatus includes a susceptor, a chamber housing that accommodates the susceptor and encloses a reaction space, and an annular baffle plate that surrounds the susceptor. The baffle plate includes a conductive material and is grounded.

According to an example embodiment of the inventive concept, a method of processing a substrate includes placing a substrate on a susceptor in a chamber housing of a substrate processing apparatus, wherein the chamber housing encloses a reaction space and accommodates an annular baffle plate that surrounds the susceptor, and the baffle plate includes a first layer that includes a conductive material and a second layer that includes a non-conductive material, and the second layer is closer to the reaction space than the first layer, supplying a processing gas into the reaction space, and applying power to a plasma generator coupled to the chamber housing to form plasma from the processing gas.

According to an example embodiment of the inventive concept, a baffle plate for a plasma processing apparatus includes a first layer that includes a conductive material and a second layer that includes a non-conductive material. The baffle plate has an annular shape.

According to an example embodiment of the inventive concept, a method of processing a substrate includes placing a substrate on a susceptor in a chamber housing of a substrate processing apparatus, wherein the chamber housing encloses a reaction space and accommodates a annular baffle plate that surrounds the susceptor, and the baffle plate includes a conductive material and is grounded, supplying a processing gas into the reaction space, and applying power to a plasma generator coupled to the chamber housing to form plasma from the processing gas.

### BRIEF DESCRIPTION OF THE DRAWINGS

FIG. 1 is a plan view that illustrates a substrate processing apparatus according to an example embodiment of the inventive concept.

FIG. 2 is a cross-sectional view that illustrates a plasma processing apparatus according to an example embodiment of the inventive concept.

FIG. 3 is a perspective view that illustrates a baffle plate according to an example embodiment of the inventive concept.

FIGS. 4A through 4G illustrate a baffle plate according to example embodiments of the inventive concept and illustrate a cross-section taken along line IV-IV′ of FIG. 3, respectively.

FIGS. 5A and 5B illustrate an electric field distribution in a reaction space when a first layer and a second layer of a baffle plate have a thickness of 5 mm, respectively,:

FIGS. 6A and 6B illustrate an electric field distribution in a reaction space when a first layer of a baffle plate has a thickness of 17 mm and a second layer of a baffle plate has a thickness of 5 mm.

FIGS. 7 through 9 illustrate a cross-section of a baffle plate that includes a stacked structure of various materials according to example embodiments of the inventive concept.

FIG. 10 is a flow chart that illustrates a method of processing a substrate according to an example embodiment of the inventive concept.

FIG. 11 is a perspective view that illustrates a structure on a substrate to be processed in a plasma processing apparatus according to an example embodiment of the inventive concept.

FIG. 12 is a block diagram that illustrates an electronic system according to example embodiments of the inventive concept;

### DETAILED DESCRIPTION OF EXAMPLE EMBODIMENTS

Herein, when two or more elements are described as being substantially the same as each other, or about the same as each other, it is to be understood that the elements are identical or equal to each other, indistinguishable from each other, or distinguishable from each other but functionally the same as each other as would be understood by a person having ordinary skill in the art.

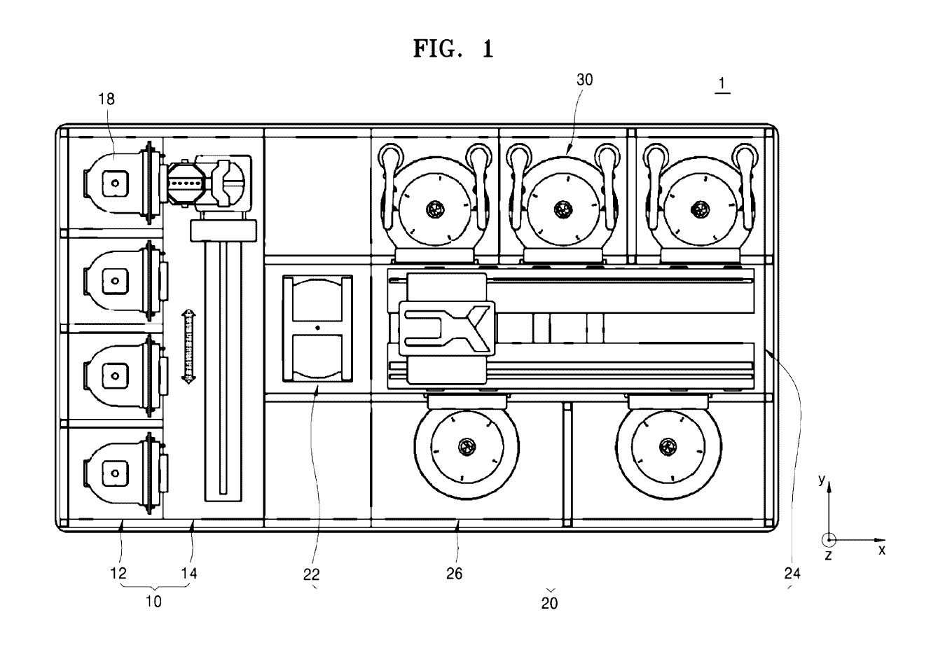

FIG. 1 is a plan view that illustrates a substrate processing apparatus according to an example embodiment of the inventive concept.

Referring to FIG. 1, a substrate processing apparatus 1 according to an embodiment includes an index module 10 and a processing module 20. The index module 10 includes a load port 12 and a transfer frame 14. In some embodiments, the load port 12, the transfer frame 14, and the processing module 20 are arranged sequentially in a line.

According to an example embodiment, a carrier 18 in which substrates are accommodated is seated on the load port 12. A front opening unified pod (FOUP) may be used as the carrier 18. There may be a plurality of load ports 12. The number of load ports 12 may increase or decrease depending on the process efficiency or foot print conditions of the processing module 20. A plurality of slots can be defined in the carrier 18 to accommodate substrates. The slots maintain the substrates parallel to the ground.

According to an example embodiment, the processing module 20 includes a buffer unit 22, a transfer chamber 24, and process chambers 26. The process chambers 26 are disposed at both sides of the transfer chamber 24. The process chambers 26 may be symmetrically arranged with respect to the transfer chamber 24.

According to an example embodiment, a plurality of process chambers 26 are provided on at least one side of the transfer chamber 24. Some of the process chambers 26 may be disposed along a length direction of the transfer chamber 24. Some of the process chambers 26 may be stacked onto each other. The process chambers 26 may be disposed on one side of the transfer chamber 24 in an “A×B” matrix. Herein, “A” indicates the number of process chambers 26 arranged in a line along an x direction, and “B” indicates the number of process chambers 26 arranged in a line along a y direction. When four or six process chambers 26 are arranged on respective sides of the transfer chamber 24, the process chambers 26 may be arranged in a “2×2” or “3×2” matrix. The number of the process chambers 26 may increase or decrease. In some embodiments, the process chambers 26 are disposed on only one side of the transfer chamber 24. In other embodiments, the process chambers 26 are disposed on one side or both sides of the transfer chamber 24 in a single layer.,

According to an example embodiment, the buffer unit 22 is disposed between the transfer frame 14 and the transfer chamber 24. The buffer unit 22 provides a space for temporarily storing a substrate before the substrate is transferred between the process chamber 26 and the carrier 18. The transfer frame 14 transfers a substrate between the buffer unit 22 and the carrier 18 in the load port 12.

According to an example embodiment, the transfer Chamber 24 transfers a substrate between the buffer unit 22 and the process chamber 26 and between the process chambers 26. A plasma processing apparatus 30 that performs a plasma treatment, such as an apparatus that performs a hydrogen plasma treatment, is provided in the process chamber 26.

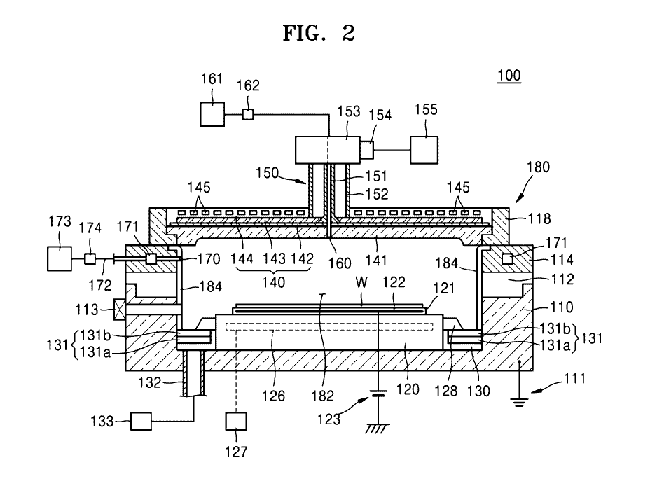

Hereinafter, the plasma processing apparatus 30 will be described. FIG. 2 is a cross-sectional view that illustrates a hydrogen plasma annealing treatment apparatus 100 as an example of the plasma processing apparatus 30 according to an example embodiment of the inventive concept.

Referring to FIG. 2, a hydrogen plasma annealing treatment apparatus 100 according to an embodiment includes a lower chamber 110. A lower gas ring 112, an upper gas ring 111, and a dome plate 118 are sequentially coupled over the lower chamber 110. A dome 141 is provided as a ceiling of a reaction space 182. The lower chamber 110, the lower gas ring 112, the upper gas ring 114, the sidewall liner 184, the dome plate 118, and the dome 141 constitute a chamber housing 180, i.e., a reaction chamber. The chamber housing 180 has the reaction space 182 therein.

According to an example embodiment, a susceptor 120 is provided at a bottom of the lower chamber 110 as a support member on which a substrate W can be placed, the susceptor 120 is provided to support the substrate W. The susceptor 120 is accommodated, i.e., contained, in the chamber housing 180. The susceptor 120 may have a cylindrical shape. The susceptor 120 may be formed of an inorganic material such as quartz or AlN, or a metal such as aluminium.

According to an example embodiment, an electrostatic chuck 121 is provided on the susceptor 120. The electrostatic chuck 121 is configured as a structure in which an electrode 122 is inserted into an insulating member. The electrode 122 is connected to a direct current power supply 123 installed outside the lower chamber 110. The substrate W electrostatically adheres to the susceptor 120 due to coulombic forces generated on a surface of the susceptor 120 by the direct current power supply 123.

According to an example embodiment, a heater/cooler 126 is provided inside the susceptor 120. The heater/cooler 126 is connected to a temperature controller 127 to control heating/cooling intensity. The temperature controller 127 can control the temperature of the susceptor 120, thereby maintaining the substrate W on the susceptor 120 at a desired temperature.

According to an example embodiment, a susceptor guide 128 is provided around the susceptor 120 to guide the susceptor 120. The susceptor guide 128 is formed of an insulating material, such as ceramic or quartz.

According to an example embodiment, a lift pin is embedded inside the susceptor 120 to support and elevate the substrate W. The lift pin can move vertically through a penetration hole formed in the susceptor 120 and protrude from a top surface of the susceptor 120. Three or more lift pins may be provided to support the substrate W.

According to an example embodiment, an exhaust space 130 is disposed around the susceptor 120 to annularly enclose the susceptor 120. An annular baffle plate 131 in which a. plurality of exhaust holes are formed is provided at a top side or in an upper portion of the exhaust space 130. The baffle plate 131 can uniformly exhaust gas phase material from the hydrogen plasma annealing treatment apparatus 100. The baffle plate 131 annularly surrounds the susceptor 120. The baffle plate 131 includes a first layer 131a and a second layer 131b on the first layer 131b. The second layer 131b is positioned closer to the reaction space 182 than the first layer 131a. The baffle plate 131 will be described in more detail below.

According to an example embodiment, an exhaust line 132 is connected to the exhaust space 130 at a bottom side of the exhaust space 130. The bottom side of the exhaust space 130 corresponds to a bottom surface of the hydrogen plasma annealing treatment apparatus 100. The number of the exhaust lines 132 may be set arbitrarily. For example, a plurality of exhaust lines 132 can be provided about a circumference of the exhaust space 130. The exhaust lines 132 may be connected to, for example, an exhaust apparatus 133 that includes a vacuum pump. The exhaust apparatus 133 can evacuate the internal atmosphere of the hydrogen plasma annealing treatment apparatus 100 to a predetermined vacuum pressure.

According to an example embodiment, a radio frequency (RF) antenna apparatus 140 which supplies microwave radiation to generate plasma is provided on a top side of the dome 141. The RF antenna apparatus 140 includes a slot plate 142, a slow-wave plate 143, and a shield lid 144.

According to an example embodiment, the dome 141 is formed of an insulating material, such as quartz, Al₂O₃, AlN, or Y₂O₃, that is transparent to the microwave radiation. The dome 141 can be attached to the dome plate 118 using a sealing member, such as an O-ring.

According to an example embodiment, the slot plate 142 is placed on the top side of the dome 141 opposite from the susceptor 120. The slot plate 142 includes a plurality of slots formed therein and can function as an antenna. The slot plate 142 is formed of a conductive material or a metal, such as copper, aluminium, or nickel.

According to an example embodiment, the slow-wave plate 143 is disposed on the slot plate 142 and can reduce the wavelength of the microwave radiation. The slow-wave plate 143 is formed of an insulating material or a low loss dielectric material, such as quartz, Al₂O₃, AlN, or Y₂O₃

According to an example embodiment, the shield lid 144 is disposed on the slow-wave plate 143 to cover the slot plate 142 and the slow-wave plate 143. A plurality of circulation-type coolant flow paths 145 are provided in the shield lid 144. The dome 141, the slow-wave plate 143, and the shield lid 144 are controlled to maintain a predetermined temperature by the coolant flowing through the coolant flow paths.

According to an example embodiment, a coaxial waveguide 150 is connected to a central portion of the shield lid 144. The coaxial waveguide 150 includes an inner conductor 151 and an outer conductor 152. The inner conductor 151 is connected to the slot plate 142. The inner conductor 151 has a conical shape adjacent to the slot plate 142 and can efficiently transmit the microwave radiation to the slot plate 142.

According to an example embodiment, the coaxial waveguide 150 is sequentially connected to a mode converter 153 which converts the microwave radiation into a predetermined oscillation mode, to a rectangular waveguide 154, and to a microwave generator 155. The microwave generator 155 can generate a microwave radiation of a predetermined frequency, such as 2.45 GHz, Power of about 2000 W can be applied to the microwave generator 155. In some embodiments, more than about 2000 W of power can he applied to the microwave generator 155. For example, about 3000 W to about 3500 W of power can be applied to the microwave generator 155.

A method of generating plasma in the hydrogen plasma annealing treatment apparatus 100 may be a capacitive type or an inductive type. Alternatively, the hydrogen plasma annealing treatment apparatus 100 can be connected to a remote plasma generator such as a plasma tube.

By such a configuration, a microwave radiation generated by the microwave generator 155 can sequentially propagate through the rectangular waveguide 154. The mode convertor 153, and the coaxial wave guide 150 into the RF antenna apparatus 140. The microwave radiation is compressed into a short wavelength by the slow wave plate 143, and after being circularly polarized by the slot plate 142, propagates from the slot plate 142 through the dome 141 into the reaction space 182. In the reaction space 182, the microwave radiation forms a plasma from a processing gas, to perform a plasma treatment on the substrate W.

According to an example embodiment, herein, the RF antenna apparatus 140, the coaxial waveguide 150, the mode convertor 153, the rectangular waveguide 154, and the micro wave generator 155 constitute a plasma generator.

According to an example embodiment, a first gas supply line 160 that supplies a gas is provided in a central portion of the RF antenna apparatus 140. The first gas supply line 160 passes through the RF antenna apparatus 140. The first gas supply line 160 has an open first end portion which passes through the dome 141. The first gas supply 160 passes through the inner conductor 151 of the coaxial waveguide 150 and through the mode convertor 153 and has a second end portion connected to a first gas supply source 161. The first gas supply source 161 can contain a processing gas, such as a hydrogen (H₂) gas. In some embodiments, the first gas supply source 161 can further contain as the processing gas a trisilylamine (TSA) gas, a N₂ gas, a H₂ gas, andor an Ar gas. In addition, a first supply control member 162, such as a valve or a flow rate controller which controls gas flow, is installed in the first gas supply line 160. The first gas supply line 160, the first gas supply source 161, and the first supply control member 162 constitute a first gas supply unit.

According to an example embodiment, at a sidewall of the chamber housing 180, as illustrated in FIG. 2, a second gas supply line 170 is provided for supplying gas. A plurality of second gas supply lines 170 may be respectively installed at the circumferential sidewall of the chamber housing 180. An example, non-limiting number of second gas supply lines 170 is 24. The plurality of the second supply lines 170 are spaced apart by a same distance. The second supply lines 170 have an open first end portion in communication with the reaction space 182 and a second end portion connected to a buffer member 171.

According to an example embodiment, the buffer member 171 is annularly disposed in the sidewall of the chamber housing 180 and is connected to each of the plurality of the second gas supply lines 170. The buffer member 171 is connected to a second gas supply source 173 via a supply line 172. The second gas supply source 173 can contain as the processing gas a trisilylamine (TSA) gas, a N₂ gas, a H₂ gas, or an Ar gas. In addition, a second supply control member 174, such as a valve or a flow rate controller which controls gas flow, is installed in the supply line 172. As illustrated in FIG. 2, gas supplied from the second gas supply source 173 is introduced into the buffer member 171 via the supply line 172, and after the flow rate or pressure of the gas in the buffer member 171 is controlled to be uniform along a circumferential direction, is supplied into the chamber housing 180 via the second gas supply line 170. The second gas supply line 170, the buffer member 171, the supply line 172, the second gas supply source 173, and the second supply control member 174 constitute a second gas supply unit.

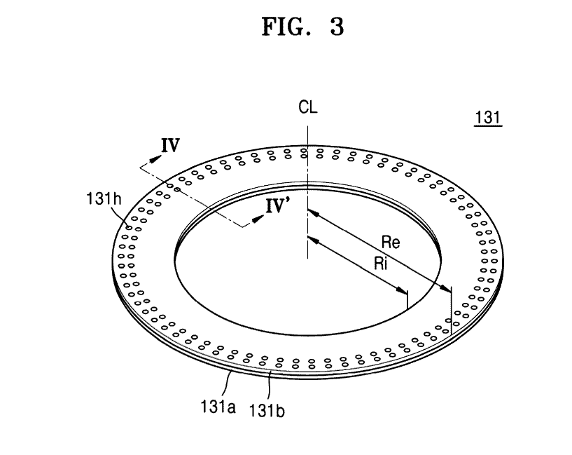

FIG. 3 is a perspective view that illustrates a baffle plate according to an example embodiment of the inventive concept.

Referring to FIG. 3, according to an example embodiment, the baffle plate 131 includes a first layer 131a and a second layer 131b. The first and second layers 131a and 131b have a concentric axis CL. In addition, the first and second layers 131a and 131b include a central opening that can accommodate the susceptor 120 of FIG. 2.

According to an example embodiment, as shown in FIG. 3, the first and second layers 131a and 131b have a circular shape, and the central opening also has a circular shape. Herein, let a length from the concentric axis CL to the circumference of the first and second layers 131a and 131b be defined as an outer radius Re. Further, let a length from the concentric axis CL to a circumference of the central opening be defined as an inner radius Ri.

In some embodiments, the outer radius Re of the first layer 131a and the outer radius Re of the second layer 131b are not necessarily equal to each other. In some embodiments, the outer radius Re of the first layer 131a and the outer radius Re of the second layer 131b are the same.

In some embodiments, the inner radius Ri of the first layer 131a and the inner radius Ri of the second layer 131b are not necessarily equal to each other. In some embodiments, the inner radius Ri of the first layer 131a and the inner radius Ri of the second layer 131b are the same.

According to an example embodiment, the baffle plate 131 includes a plurality of peripheral openings 131h passing through the first and second layers 131a and 131b. Each peripheral opening 131h penetrates the first and second layers 131a and 131b at the same location. The peripheral openings 131h can act as a channel through which used gases or by-products can flow from the reaction space 182 of FIG. 2 into the exhaust space 130 of FIG. 2

According to an example embodiment, the first layer 131a is made of a conductive material. The first layer 131a may be made from a metal, such as at least one of aluminium (Al), copper (Co), stainless steel, and titanium (Ti), but embodiments are not limited thereto. In some embodiments, the first layer 131a. is made of aluminium (Al).

According to an example embodiment, the second layer 131b is made of a non-conductive material. The second layer 131b may be made from at least one of quartz, Al₂O₃, AlN, and Y₂O₃, but embodiments are not limited thereto. In some embodiments, the second layer 131b is made of quartz.

The first and second layers 131a and 131b may have the same thickness or different thicknesses.

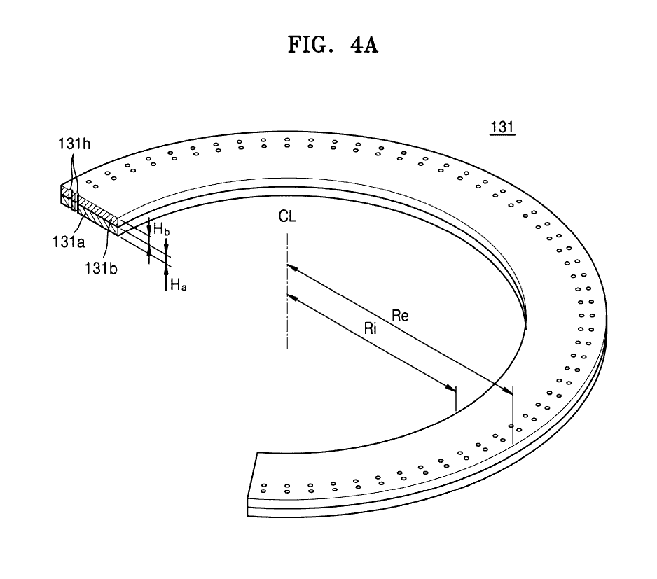

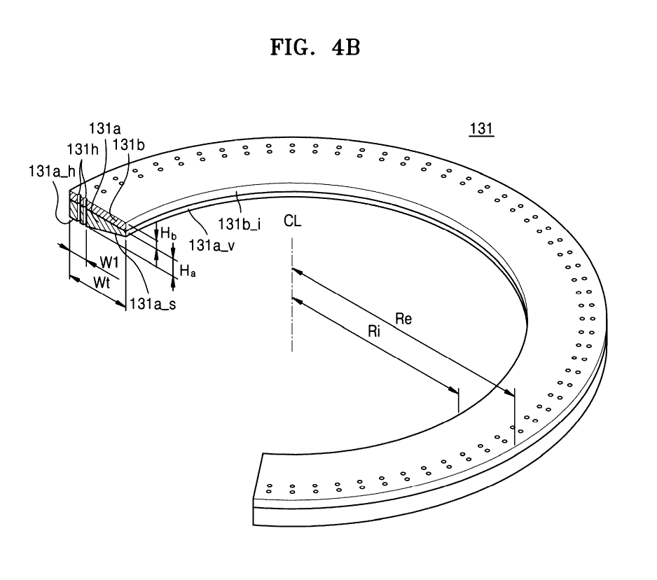

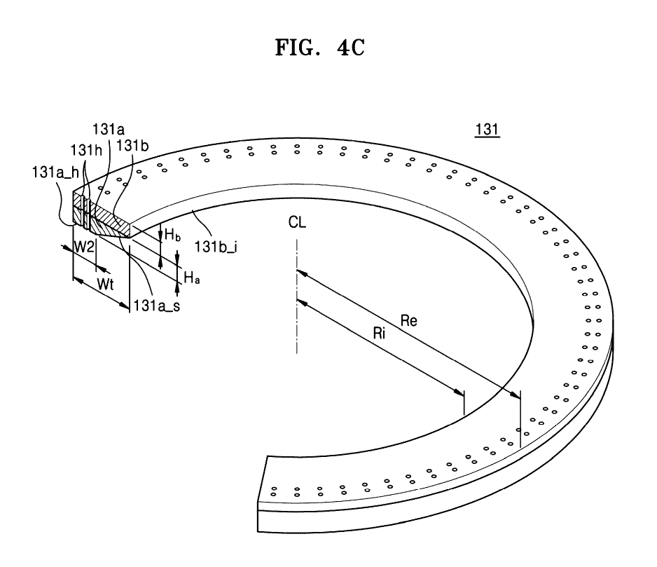

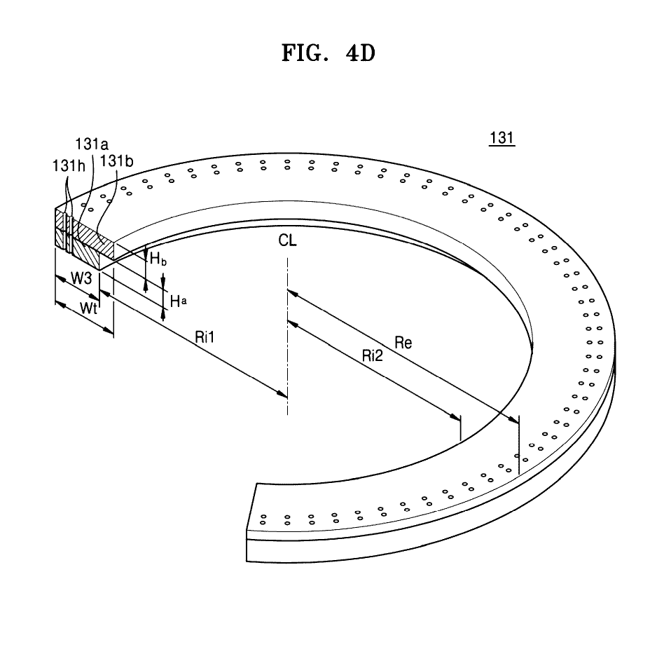

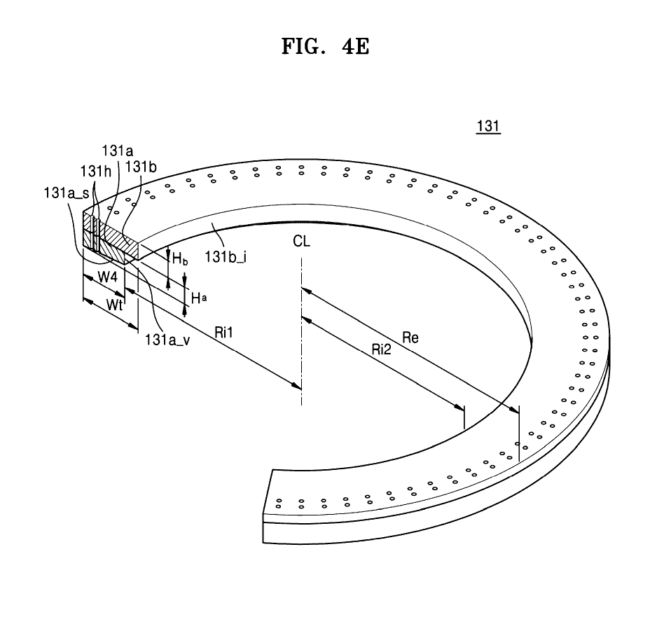

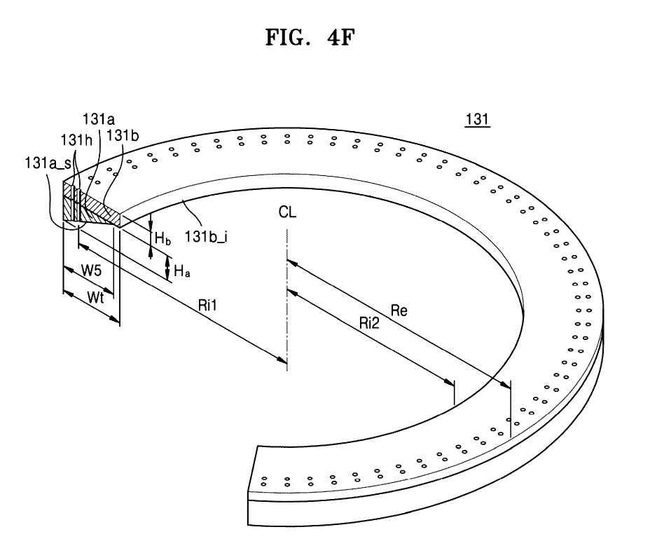

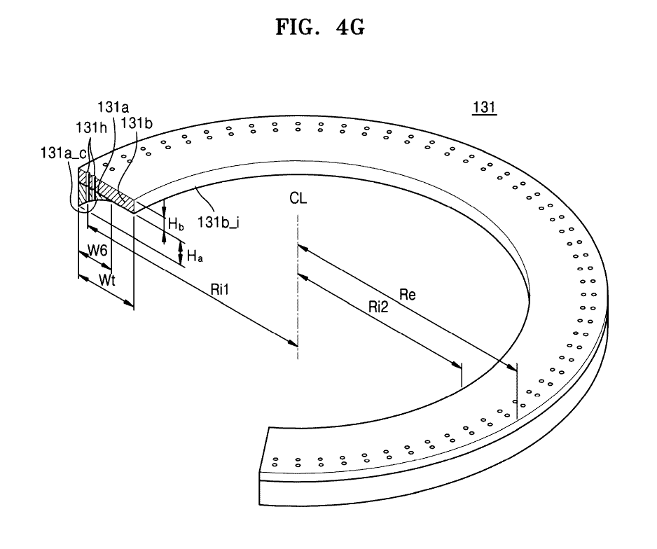

FIGS. 4A through 4G illustrate a baffle plate according to example embodiments of the inventive concept, and illustrate a cross-section taken along line IV-IV′ of FIG. 3, respectively.

Referring to FIG. 4A, according to an example embodiment, the first and second layers 131a and 131b have substantially the same outer radius Re and substantially the same inner radius Ri. In the first layer 131a, the outer radius Re and the inner radius Ri are constant along the concentric axis CL, i.e., in a thickness direction parallel to the concentric axis CL. In the second layer 131b, the outer radius Re and the inner radius Ri are constant along the concentric axis CL. A cross-section of the first layer 131a in a radial direction has a tetragonal shape. For example, a radial cross-section of the first layer 131a has a rectangular shape.

According to an example embodiment, a thickness Ha of the first layer 131a is equal to a thickness Hb of the second layer 131b. The thicknesses Ha and Hb of the first and second layers 131a and 131b are in a range of about 10 min to about 50 mm.

Likewise, according to an example embodiment, since the baffle plate 131 has a double layered structure formed of the first layer 131a and the second layer 131b, the probability of generating an arc in the reaction space 182 of FIG. 2 is decreased. When an arc is generated in the reaction space 182 of FIG. 2, many particles that can contaminate the substrate W can be created, and thus production yield can be reduced. A conventional baffle plate is made from a non-conducive material such as quartz. By comparison, when the baffle pate 131 that includes the conductive first layer 131a in addition to the non-conductive second layer 131b is used, and the conductive first layer 131a is properly grounded, arc generation in the reaction space is decreased.

Referring to FIG. 4B, according to an example embodiment, the first layer 131a and the second layer 131b have the same outer radius Re and the same inner radius Ri. In the second layer 131b, the outer radius Re and the inner radius Ri are constant along the concentric axis CL. In the first layer 131a, the outer radius Re is constant along the concentric axis CL.

However, according to an example embodiment, the first layer 131a includes a portion in which the inner radius Re varies along the concentric axis CL. An inner surface of the first layer 131a includes a portion 131av that extends parallel to the concentric axis CL. In addition, the inner surface of the first layer 131a includes a portion 131 a_s that is obliquely sloped relative to the concentric axis CL. A bottom surface of the first layer 131a has a portion 131a_h that extends in a direction perpendicular to the concentric axis CL.

Let the thickness Ha of the first layer 131a be defined as a maximum thickness thereof in a direction parallel to the concentric axis CL. According to an example embodiment, the thickness Ha of the first layer 131a is in a range of about 10 mm to about 50 mm. The thickness Ha of the first layer 131a decreases closer to an inner sidewall or inner surface 131b_i of the second layer 131b.

If the thickness Ha of the first layer 131a is too great, the baffle plate 131 may not be installed due to mechanical interference between the baffle plate and an apparatus in which the baffle plate is installed. If the thickness Ha of the first layer 131a is too small, the ability of the first layer 131a to evenly distribute an electric field in the reaction space is degraded.

When the thickness Ha of the first layer 131a increases, an electric field distribution in the reaction space becomes more uniform. When the thickness Ha of the first layer 131a is in a range of about 3 mm to about 7 mm, the first layer 131a can reduce arc generation as described with reference to FIG. 4A, but the electric field is not evenly distributed in the reaction space. However, when the thickness Ha of the first layer 131a is in a range of about 10 mm or more, the first layer 131a can both reduce arc generation and evenly distribute the electric field in the reaction space. When the electric field distribution in the reaction space is more uniform, surface treatments, material depositions, material etches, etc., can be more uniformly performed on an overall surface of the substrate W of FIG. 2.

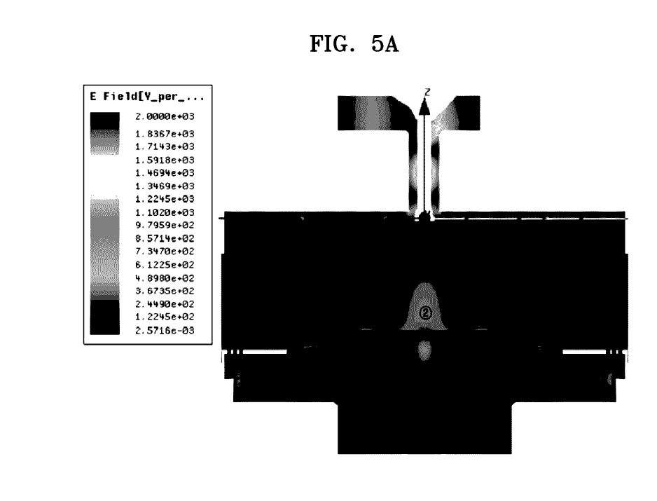

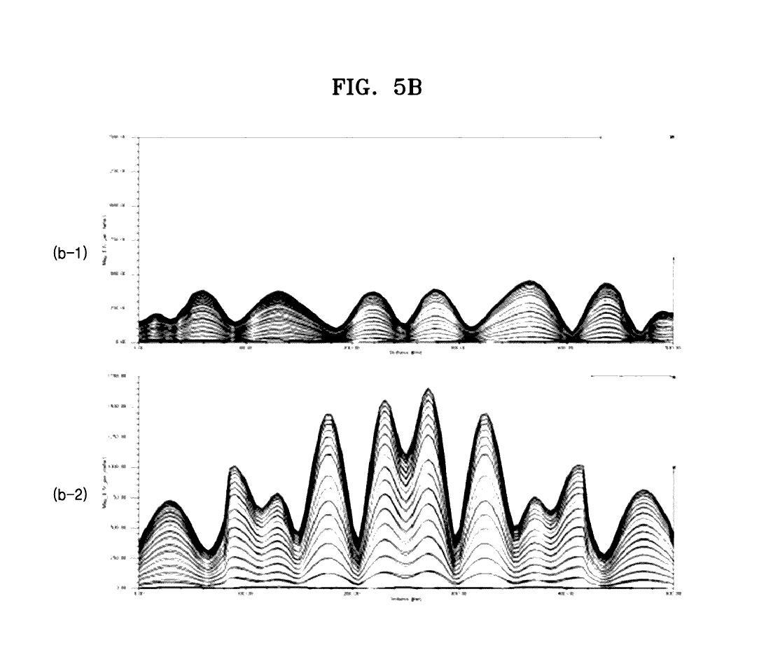

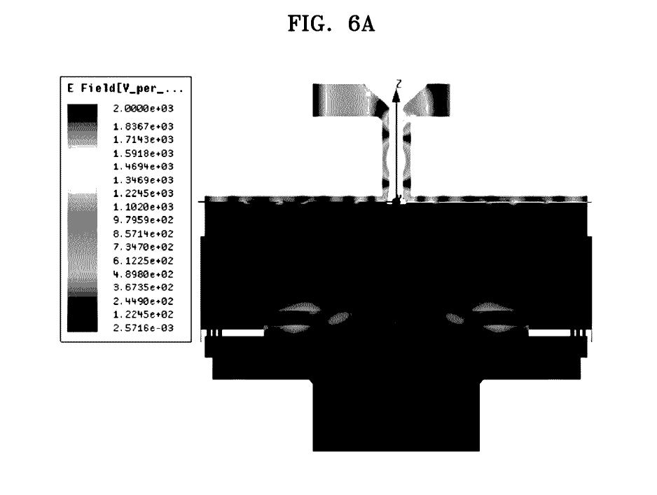

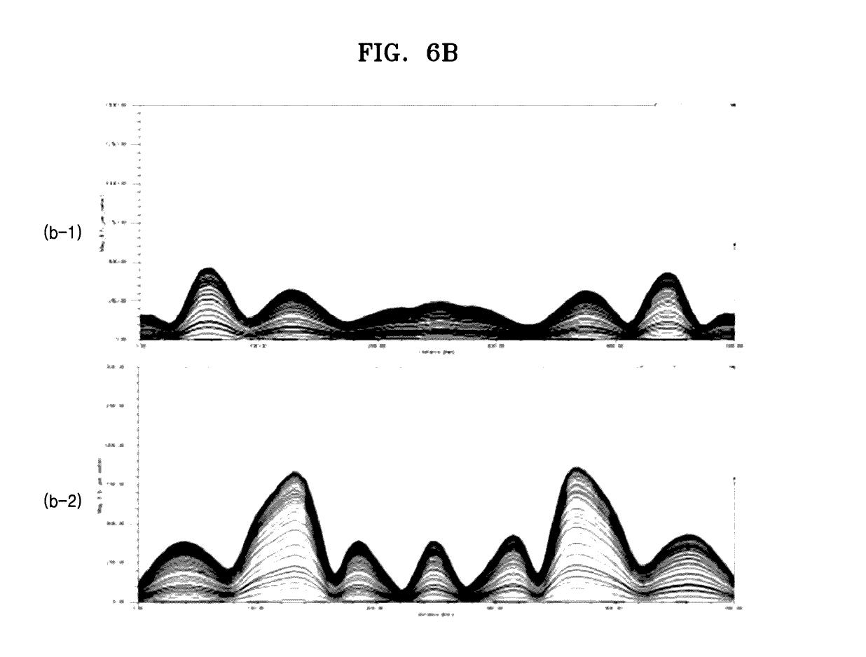

FIGS. 5A and 5B illustrate an electric field distribution in a reaction space when a first layer 131a and a second layer 131b have a thickness of 5 mm, respectively. FIGS. 6A and 6B illustrate an electric field distribution in a reaction space when a first layer 131a has a thickness of 17 mm and a second layer 131b has a thickness of 5 mm. According to an embodiment, the first layer 131a is made of aluminum, and the second layer 131b is made of quartz.

In FIGS. 5A and 6A, the brightness represents an electric field intensity. In FIGS. 5B and 6B, a horizontal axis represents a position in a radial direction on the substrate, and a vertical axis represents the electric field intensity.

When comparing FIG. 5A and FIG. 6A, intensity differences between dark regions and pale regions are less in FIG. 6A than in FIG. 5A. Thus, the electric field intensity in the reaction space is more uniform when the first layer 131a has a thickness of 17 mm than when the first layer 131a has a thickness of 5 mm.

A (b-1) graph of FIGS. 5B and 6B represents the electric field intensity along the radial direction of the substrate at a position \textcircled{1} in FIGS. 5A and 5B, and a (b-2) graph of FIGS. 5B and 6B represents the electric field intensity along the radial direction of the substrate at a position \textcircled{2} in FIGS. 5A and 5B.

When comparing FIG. 5B and FIG. 6B, an amplitude of a wave is much smaller in FIG. 6B than in FIG. 5B. As result, the electric field distribution in the reaction space is more uniform when the first layer 131a is thicker, such as 17 mm.

Referring again to FIG. 4B, according to an embodiment, the second layer 131b has a width Wt. The first layer 131a also has a maximum width Wt in the radial direction, while a portion 131a_h that extends perpendicular to the concentric axis CL has a width W1. A cross-section in the radial direction has a pentagonal shape.

Referring to FIG. 4C, according to an embodiment, the first layer 131a and the second layer 131b have the same outer radius Re and the same inner radius Ri. In the second layer 131b, the outer radius Re and the inner radius Ri are constant along the concentric axis CL. In the first layer 131a, the outer radius Re is constant along the concentric axis CL.

However, according to an embodiment, the first layer 131a has a portion in which the inner radius R1 varies along the concentric axis CL. An inner surface of the first layer 131a has a portion 131 a_s which is obliquely sloped relative to concentric axis CL without a portion parallel to the concentric axis CL. In other words, the inner radius Ri of the portion 131a_s of the inner surface of the first layer 131a decreases as the first layer 131a slopes closer to the second layer 131b in a direction parallel to the concentric axis CL. A bottom surface of the first layer 131a also has a portion 131a_h that extends in a direction perpendicular to the concentric axis CL.

According to an embodiment, the height Ha of the first layer 131a is in a range of about 10 mm to about 50 mm. The thickness Ha of the first layer 131a decreases closer to an inner sidewall or inner surface 131b i of the second layer 131b.

According to an embodiment, the second layer 131b has a width Wt. The first layer 131a has a maximum width Wt in the radial direction. A portion 131a_h of the first layer 131a has a width W2 in the radial direction. A cross-section of the first layer 131a in the radial direction has a tetragonal shape, such as a trapezoidal shape.

Referring to FIG. 4D, according to an embodiment, the first layer 131a and the second layer 131b have the same outer radius Re. However, an inner radius Ri1 of the first layer 131a differs from an inner radius Ri2 of the second layer 131b. In some embodiments, the inner radius Ri1 of the first layer 131a is greater than the inner radius Ri2 of the second layer 131b.

According to an embodiment, the first layer 131a has a width W3, and the second layer 131b has a width Wt. The width Wt is greater than the width W3. A cross-section of the first layer 131a in the radial direction has a tetragonal shape, such as a rectangular shape.

According to an embodiment, the first layer 131a has a thickness Ha of about 10 mm to about 50 mm.

Referring to FIG. 4E, according to an embodiment, the first layer 131a and the second layer 131b have the same outer radius Re. However, an inner radius Ri1 of the first layer 131a differs from an inner radius Ri2 of the second layer 131b. In some embodiments, the inner radius Ri1 of the first layer 131a is greater than the inner radius Ri2 of the second layer 131b.

According to an embodiment, an inner surface of the first layer 131a has a portion 131a_s for which the inner radius Ri1 varies with a distance from the concentric axis CL. The portion 131a_s of the inner surface of the first layer 131a is obliquely sloped relative to the concentric axis CL. The inner surface of the first layer 131a has a portion 131a_v that extends parallel to the concentric axis CL. The inner radius Ri1 of the portion 131a_s of the inner surface of the first layer 131a decreases as the portion 131a_s slopes closer to the second layer 131b in a direction parallel to the concentric axis CL.

According to an embodiment, the first layer 131a has a width W4, and the second layer 131b has a width Wt. The width Wt is greater than the width W4. A cross-section of the first layer 131a in a radial direction may have a tetragonal shape, for example, a trapezoidal shape.

According to an embodiment, a thickness of the first layer 131a is in a range of about 10 mm to about 50 mm. The thickness Ha of the first layer 131a decreases closer to an inner sidewall or inner surface 131b_i of the second layer 131b.

Referring to FIG. 4F, according to an embodiment, the first layer 131a and the second layer 131b have the same outer radius Re. However, an inner radius Ri1 of the first layer 131a differs from an inner radius Ri2 of the second layer 131b. In some embodiments, the inner radius Ri1 of the first layer 131a is greater than the inner radius Ri2 of the second layer 131b,

According to an embodiment, an inner surface of the first layer 131a has a portion 131a_s for which the inner radius Ri1 varies according to a distance from the concentric axis CL. The portion 131a_s of the inner surface of the first layer 131a is obliquely sloped relative to the concentric axis CL. The inner radius Ri1 of the inner surface 131a_s of the first layer 131a decreases as the inner surface 131a_s slopes closer to the second layer 131b in direction parallel to the concentric axis CL. In other words, the inner radius Ri1 of the first layer 131a 131b relative to the concentric axis CL decreases closer to the second layer.

According to an embodiment, the first layer 131a has a width W5, and the second layer 131b has a width Wt. The width Wt is greater than the width W5. A cross-section of the first layer 131a in the radial direction has a triangular shape.

According to an embodiment, a thickness of the first layer 131a is in a range of about 10 mm to about 50 mm. The thickness Ha of the first layer 131a decreases closer to an inner sidewall or inner surface 131b_i of the second layer 131b.

Referring to FIG. 4G, according to an embodiment, the first layer 131a and the second 131b have the same outer radius Re. An inner radius Ri1 of the first layer 131a differs from an inner radius Ri2 of the second layer 131b. In some embodiments, the inner radius Ri1 of the first layer 131a is greater than the inner radius Ri2 of the second layer 131b.

According to an embodiment, an inner surface of the first layer 131a has a portion 131a_c for which the inner radius Ri1 varies along the concentric axis CL. The inner surface 131a_c of the first layer 131a is concavely rounded. The inner surface 131a_c of the first layer 131a is a surface curved toward the second layer 131b. The inner radius Ri1 of the inner surface 131a_c of the first layer 131a decreases closer to the second layer 131b in a direction parallel to the concentric axis CL. A tangential plane at any point in the inner surface 131a_c of the first layer 131a forms an angle that is obliquely inclined relative to the concentric axis CL.

According to an embodiment, the first layer 131a has a width W6, and the second layer 131b may have a width Wt. The width Wt is greater than the width W6. The first layer 131a has a height of about 10 mm to about 50 mm. The thickness Ha of the first layer 131a decreases closer to an inner sidewall or inner surface 131b_i of the second layer 131b.

It will be understood by those of ordinary skill in the art that the embodiments described with reference to FIGS. 4A through 4G can be combined with each other or modified so as to configure other embodiments. As an example, the sloped portion 131a_s of FIG. 4C can be modified so as to be curved toward the second layer 131b. As another example, an inner sidewall, such as the portion 131a_v, of the first layer 131a shown in FIG. 4B can be modified to be cut off, such that the inner sidewall, i.e, the portion 131a_v, of the first layer 131a is further from the concentric axis as shown in FIG. 4E.

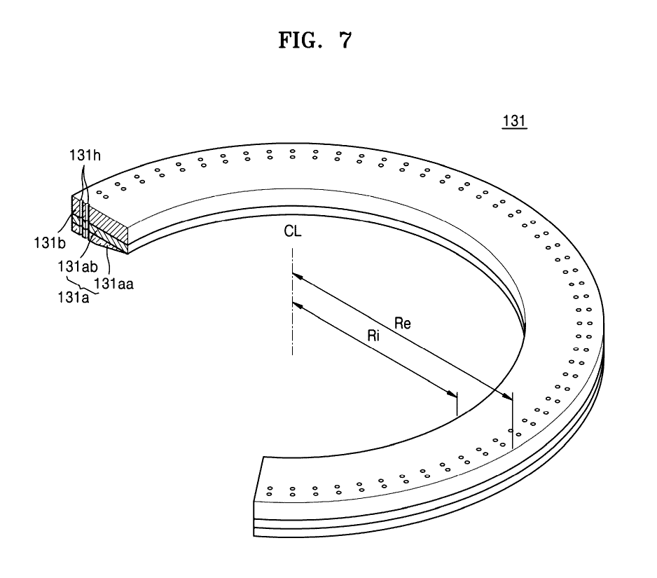

According to an embodiment, the baffle plate 131 includes a stacked structure formed of various materials. FIGS. 7 through 9 illustrate a cross-section of a baffle plate that includes a stacked structure of various materials according to example embodiments of the inventive concept.

Referring to FIG. 7, according to an embodiment, the first layer 131a of the baffle plate 131 includes two or more metal layers. For example, the first layer 131a includes a first metal layer 131aa and a second metal layer 131ab. The first metal layer 131aa and the second metal layer 131ab are made from different materials. The first metal layer 131aa and the second metal layer 131ab respectively include at least one of aluminium (Al), copper (Co), stainless steel, and titanium (Ti)

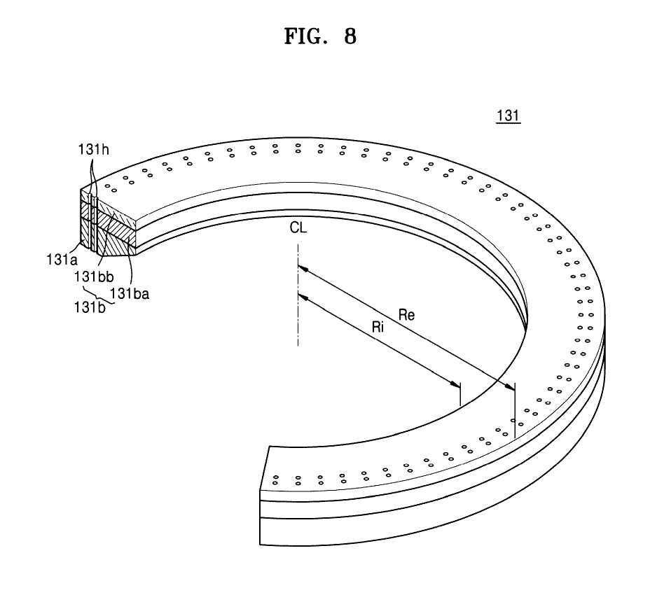

Referring to FIG. 8, according to an embodiment, the second layer 131b of the baffle plate 131 includes two or more insulating layers. For example, the second layer 131b includes a first insulating layer 131b a and a second insulating layer 131bb. The first insulating layer 131ba and the second insulating layer 131bb are made from different insulating materials. The first insulating layer 131ba and the second insulating layer 131bb respectively include at least one of quartz, Al₂O₃, AlN, and Y₂O₃.

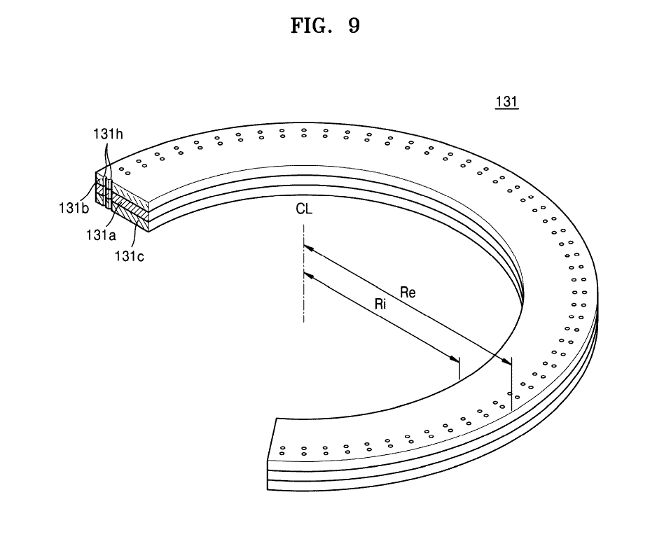

Referring to FIG. 9, according to an embodiment, the baffle plate 131 includes a third layer 131c adjacent to the first layer 131a and opposite to the second layer 131b, so that the first layer 131a is interposed between the second layer 131b and the third layer 131c. The third layer 131c includes a non-conductive material. The first layer 131a includes a conductive material and the second layer 131b includes a non-conductive material. The second layer 131b and the third layer 131c are made from different insulating material. The second layer 131b and the third layer 131c respectively include at least one of quartz, Al₂O₃, AlN, and Y₂O₃. Each of the peripheral openings 131h also penetrates the third layer 131c at the same location as the first and second layers 131a and 131b.

Referring again to FIG. 2, according to an embodiment, the baffle plate 131 is electrically connected to the lower chamber 110, which is made from a conductive metal. The baffle plate 131 can he grounded through a ground member 111. In this case, the baffle plate 131 can act as a ground path due to the electrical connection with the lower chamber 110.

According to an embodiment, a sidewall liner 184 is disposed on an inner sidewall of the reaction space 182 of the chamber housing 180 to protect the lower chamber 110, the lower gas ring 112, and the upper gas ring 114 from plasma. The sidewall liner 184 is made from an insulating material such as quartz, Al₂O₃, AlN, or Y₂O₃. In addition, a gate valve 113 that penetrates the lower chamber 110 and the sidewall liner 184 is provided. The gate valve 113 provides an entry into the lower chamber 110.

According to an embodiment, the sidewall liner 184 covers an exposed area of the upper gas ring 114 along with an exposed sidewall of the lower chamber 110. Thus, the lower chamber 110, the lower gas ring, and the upper gas ring can be completely protected from plasma.

Hereinafter, a method of processing a substrate using a hydrogen plasma annealing treatment apparatus 100 will be described.

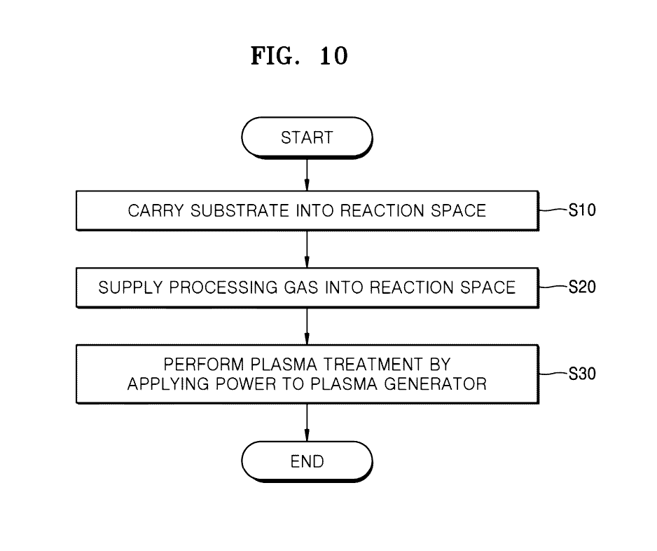

FIG. 10 is a flow chart that illustrates a method of processing a substrate according to an example embodiment of the inventive concept.

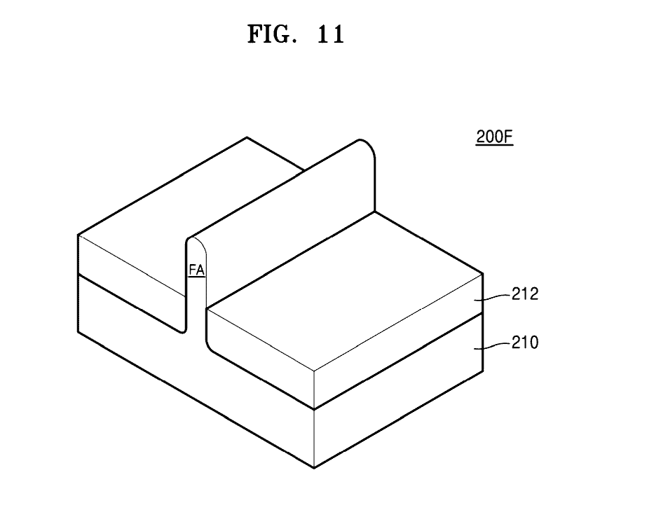

Referring to FIGS. 2 and 10, the substrate W can be carried into the reaction space 182 through the gate valve 113 (S10). According to an embodiment, the substrate W is a semiconductor substrate on which a structure for manufacturing a semiconductor device is formed. FIG. 11 is a perspective view illustrating such a structure 200F.

Referring to FIG. 11, according to an embodiment, a semiconductor substrate 210 on which a fin type active region FA is formed is provided.

The semiconductor substrate 210 may include a semiconductor material such as Si or Ge, or a semiconductor compound such as SiGe, SiC, GaAs, InAs, InP. In some embodiments, the semiconductor substrate 210 includes a III-V group semiconductor material and a IV group semiconductor material. The III-V group semiconductor material may include a binary compound, a ternary compound, or a quaternary compound, each of which contains at least one III group element and at least one V group element. The III-V group semiconductor compound includes a III group element, such as at least one of In, Ga, and Al, and a V group element, such as at least one of As, P and Sb. For example, the III-V group semiconductor material includes InP, In_{z}Ga_{1-z}As (0≦z≦1), or AL_{z}Ga_{1-z}As (0≦z≦1). The binary compound includes, for example, any one of InP, GaAs, InAs, InSb, or GaSb. The ternary compound includes, for example, any one of: InGaP, InGaAs, AlInAs, InGaSb, GaAsSb, or GaAsP. The IV group semiconductor material includes, for example, Si or Ge. However, the III-V or IV group semiconductor materials are not limited thereto. The III-V group semiconductor material and the IV group semiconductor material such as Ge can be used as a channel material to implement a low power, high speed transistor. A high performance transistor, such as a high performance CMOS transistor, can formed using a III-V group semiconductor substrate or a III-V group semiconductor material that includes, for example, GaAs, which has a higher electron mobility than a silicon substrate, and a IV group semiconductor material that includes, for example, Ge, which has a higher hole mobility than a silicon substrate.

In some embodiments, when an NMOS transistor is formed on the semiconductor substrate 210, the semiconductor substrate 210 may include any one of the III-V group semiconductor materials as described above. In some embodiments, when a PMOS transistor is formed on the semiconductor substrate 210, at least a portion of the semiconductor substrate 210 includes Ge. In some embodiments, the semiconductor substrate 210 includes a silicon on insulator (SOI) substrate. The semiconductor substrate 210 may include a conductive region, such as a well doped with dopants, or a structure doped with dopants.

According to an embodiment, a device isolation layer 212 that isolates the fin type active region FA is provided on sidewalls of the fin type active region FA. In some embodiments, the device isolation layer 212 may include a silicon oxide layer, a silicon nitride layer, a silicon oxynitride layer, a silicon carbonitride layer, a poly-silicon layer, or a combination thereof. The device isolation layer 212 may be formed by a plasma enhanced chemical vapor deposition (PECVD) process, a high density plasma chemical vapor deposition (HDP CVD) process, an inductively coupled plasma chemical vapor deposition (ICP CVD) process, a capacitor coupled plasma chemical vapor deposition (CCP CVD) process, a flowable chemical vapor deposition (FCVD) process, or a spin coating process, but embodiments are not limited thereto. For example, the device isolation layer 212 may be formed of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate. (PETEOS), or tonen silazene (TOZ), but embodiments are not limited thereto.

After the fin type active region FA is patterned, roughness and crystal disorder may be present on the surface of the fin type active region FA. As a result, carrier mobility may be reduced due to the roughness and the crystal disorder.

Referring again to FIGS. 2 and 10, according to an embodiment, the substrate W, such as the substrate 210 with the structure 200F of FIG.11, is mounted on the susceptor 120 by the lift pin. At this time, a direct current is applied to the electrode 122 of the electrostatic chuck 121 by turning on the direct current power supply 123, so that the substrate W can be electrostatically adhered to the electrostatic chuck 121 by a coulombic force. After the gate valve 113 is closed to hermetically seal the reaction space 182, the exhaust apparatus 133 is operated to evacuate the reaction space 182 to a predetermined pressure, such as a pressure of 10 mTorr to 500 mTorr. The temperature of the substrate W is increased to about 450° C. to about 650° C., using the heater/cooler 126 in the susceptor 120.

According to an embodiment, a processing gas is supplied into the reaction space 182 (S20). For example, a first processing gas is supplied into the reaction space 182 through the first gas supply line 160 and a second processing gas is supplied into the reaction space 182 through the second gas supply line 170. Argon (Ar) gas is supplied as the first processing gas at a flow rate of about 100 sccm. Hydrogen (H₂) gas is supplied as the second processing gas at a flow rate of about 750 sccm.

According to an embodiment, a plasma treatment is performed by applying power to a plasma generator (S30). For example, when argon gas and hydrogen gas are supplied, the microwave generator 155 is operated to generate a microwave radiation of a predetermined power at a frequency of, e.g., 2.45 GHz. The microwave radiation propagates through the rectangular waveguide 154, the mode convertor 153, the coaxial waveguide 150, and the RF antenna apparatus 140 into the reaction space 182. The gases, such as Ar and H₂, are plasma-excited by the microwave radiation in the reaction space 182 and dissociate into a plasma to generate active species, and the substrate W is treated with the active species. In other words, the plasma treatment is performed on the substrate W.

At this time, power of about 3000W to about 3500W is applied to the microwave generator 155. In a conventional plasma processing apparatus, power of more than 2700W may not be applied due to the arc generation. However, since a baffle plate 131 according to example embodiments of the inventive concepts is used, arc generation can be reduced or prevented. Thus, particle contamination is reduced and a broader or higher range of power can be used to process a substrate.

While the plasma treatment is performed on the substrate W, a high frequency power source may be optionally applied to output a higher frequency predetermined power at a frequency of, e.g., 13.56 MHz

Although a plasma treatment, such as a plasma annealing treatment, using a microwave radiation is described above, example embodiments of the inventive concept are not limited thereto. For example, a plasma treatment, such as a plasma annealing treatment, using a high frequency power can be used with example embodiments of the inventive concept.

In addition, although example embodiments of the inventive concept are used with a plasma treatment for a plasma annealing treatment, example embodiments of the inventive concept can be used with a substrate treatment process other than a plasma annealing treatment, such as a plasma treatment for an etching process, a sputtering process, or a deposition process. In some embodiments, a substrate to be processed by a plasma treatment includes, for example, a sapphire substrate, a glass substrate, an organic electroluminescent (EL) substrate, or a substrate for a flat panel display (FPD).

According to an embodiment, roughness or disorder of the substrate W generated in the patterning process can be removed or cured by a plasma treatment, such as a hydrogen plasma annealing treatment.

According to an embodiment, after the plasma treatment is performed, the substrate W is unloaded from the reaction space 182.

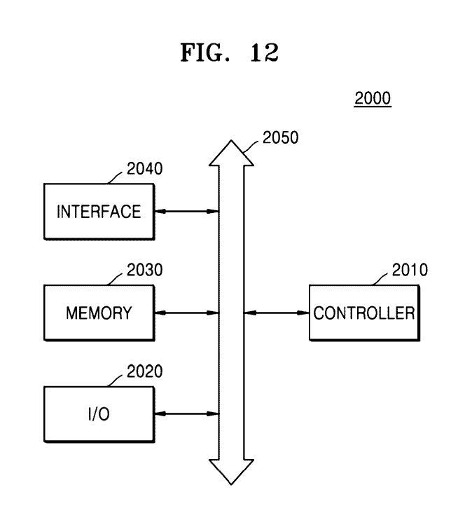

FIG. 12 is a block diagram that illustrates an electronic system according to example embodiments of the inventive concept.

Referring to FIG. 12, according to an embodiment, an electronic system 2000 includes a controller 2010, an input/output (I/O) unit 2020, a memory device 2030, an interface unit 2040, and a data bus 2050. At least two of the controller 2010, the I/O unit 2020, the memory device 2030, and the interface unit 2040 communicate with each other through the data bus 2050.

The controller 2010 may include at least one of a microprocessor, a digital signal processor, a microcontroller, or other logic devices that have a similar function. The I/O unit 2020 may include a keypad, a keyboard and/or a display unit. The memory device 2030 can be used to store commands executed by the controller 2010. The memory device 2030 can store user data.

The electronic system 2000 may form a wireless communication device, or a device that can transmit or receive information in wireless environments. The interface 2040 can be implemented with a wireless interface to help the electronic system 2000 to transmit/receive data via a wireless communication network. The interface 2040 may include an antenna and/or a wireless transceiver. According to some embodiments, the electronic system 2000 can used in a communication interface protocol of a third-generation communication system, for example, a code division multiple access (CDMA), a global system for mobile communications (GSM), a North American digital cellular (NADC), an extended-time division multiple access (E-TDMA), or a wide band code division multiple access (WCDMA). The electronic system 1100 may include at least one semiconductor device manufactured using a plasma processing apparatus and method of processing a substrate as described with reference to FIGS. 2 to 10

The above-disclosed subject matter is to be considered illustrative, and not restrictive, and the appended claims are intended to cover all such modifications, enhancements, and other embodiments, which fall within the true spirit and scope of embodiments of the inventive concept. Thus, to the maximum extent allowed by law, the scope is to be determined by the broadest permissible interpretation of the following claims and their equivalents, and shall not be restricted or limited by the foregoing detailed description.

1. A plasma processing apparatus, comprising:
a susceptor;
a chamber housing that accommodates the susceptor and encloses a reaction space; and
an annular baffle plate that surrounds the susceptor,
wherein the baffle plate includes a first layer that includes a conductive material and a second layer that includes a non-conductive material, and the second layer is closer to the reaction space than the first layer.

2. The plasma processing apparatus of claim 1, wherein the second layer includes at least one of quartz, Al₂O₃, AlN, and Y₂O₃.

3. The plasma processing apparatus of claim 1, wherein the first layer includes a metal.

4. The plasma processing apparatus of claim 3, wherein the metal includes at least one of aluminum, copper, stainless steel, and titanium.

5. The plasma processing apparatus of claim 1, wherein the first layer and the second layer have a same outer radius, and an inner radius of the first layer differs from an inner radius of the second layer.

6. The plasma processing apparatus of claim 5, wherein the inner radius of the first layer is greater than the inner radius of the second layer.

7. The plasma processing apparatus of claim 6, wherein the inner radius of the first layer and the inner radius of the second layer are constant with respect to a concentric axis of the baffle plate.

8. The plasma processing apparatus of claim 6, wherein the inner radius of the first layer varies along a direction parallel to the concentric axis of the baffle plate.

9. The plasma processing apparatus of claim 8, wherein the inner surface of the first layer includes a portion that is obliquely sloped relative to the concentric axis, and the inner radius of the first layer decreases as the portion slopes closer to the second layer.

10. (canceled)

11. The plasma processing apparatus of claim 1, wherein a maximum thickness of the first layer is in a range of 10 mm to 50 mm in a direction parallel to a concentric axis of the baffle plate.

12. The plasma processing apparatus of claim 1, wherein the first layer includes least stacked two metal layers.

13. The plasma processing apparatus of claim 1, wherein the baffle plate further comprises a third layer adjacent to the first layer and opposite to the second layer,
wherein the first layer is interposed between the second layer and the third layer.

14. The plasma processing apparatus of claim 13, wherein the third layer includes a non-conductive material.

15. The plasma processing apparatus of claim 1, wherein the first layer is electrically connected to the chamber housing.

16. (canceled)

17. The plasma processing apparatus of claim 1, wherein the baffle plate further includes a plurality of peripheral openings that penetrate the first and second layers.

18. (canceled)

19. A method of processing a substrate, comprising:
placing a substrate on a susceptor in a chamber housing of a substrate processing apparatus,
wherein the chamber housing encloses a reaction space and accommodates a annular baffle plate that annularly surrounds the susceptor, and the baffle plate includes a first layer that includes a conductive material and a second layer includes a non-conductive material, and the second layer is closer to the reaction space than the first layer;
supplying a processing gas into the reaction space; and
applying power to a plasma generator coupled to the chamber housing to form plasma from the processing gas.

20. The method of claim 19, wherein the processing gas is hydrogen.

21. The method of claim 19, wherein the baffle plate is grounded through the chamber housing.

22. The method of claim 19, wherein the power is in a range of 3000 W to 3500 W.

23-27. (canceled)

28. A method of processing a substrate, comprising:
placing a substrate on a susceptor in a chamber housing of a substrate processing apparatus,
wherein the chamber housing encloses a reaction space and accommodates a annular baffle plate that surrounds the susceptor, and the baffle plate includes a conductive material and is grounded;
supplying a processing gas into the reaction space; and
applying power to a plasma generator coupled to the chamber housing to form plasma from the processing gas.
